(19) United States
(12) Patent Application Publication
(10) Pub. No.: US 2015/0082109 A1
(43) Pub. Date: Mar. 19, 2015

(54) DETECTING DEFECTS IN A PROCESSOR SOCKET

(71) Applicant: Pritl Jayantl Patel, Houston, TX (US)

(72) Inventor: Pritl Jayantl Patel, Houston, TX (US)

(21) Appl. No.: 14/395,889

(22) PCT Filed: Jul. 30, 2012
(86) PCT No.: PCT/US2012/048847

§ 371 Date: Oct. 21, 2014

(51) Int. Cl. G01R 31/3177

(52) U.S. Cl. CPC G01R 31/3177
USPC 714/727

(57) ABSTRACT

A socket can include a plurality of pins. The socket may be tested to determine if there are any faults or defects. For example, it can be determined whether any of the plurality of pins is bent or missing.

### BACKGROUND

Microprocessors can be connected to a circuit board, such as a motherboard, via a socket. This socket can be referred to as a “processor socket.” The processor socket can have multiple prongs or pins (hereinafter referred to as “pins”) that can make electrical contact with corresponding pads on the microprocessor. When the microprocessor is inserted into the processor socket, the pin-pad combination can be referred to as a processor pin.

### BRIEF DESCRIPTION OF DRAWINGS

The following detailed description refers to the drawings, wherein:

FIG. 1 illustrates a system for detecting defects in a processor socket according to an example.

FIG. 2 illustrates a circuit diagram of a system for detecting defects in a processor socket, according to an example.

FIG. 3 illustrates a method for detecting defects in a processor socket, according to an example.

FIG. 4 illustrates a computer-readable medium for detection of defects in a processor socket, according to an example.

### DETAILED DESCRIPTION

Sometimes the pins in a processor socket can become bent or may even break off during manufacturing, during insertion of the microprocessor into the processor socket, or in other ways. When a pin is bent or missing, communication between the microprocessor and devices on the circuit board can be impaired. In the past, visual inspection has been employed to try to detect bent or missing pins.

According to an example, a system can include a socket with multiple pins, such as a processor socket. A microprocessor having an interface, such as a Joint Test Action Group (JTAG) interface, can be installed in the processor socket. The JTAG interface can provide testing and debugging functionality. The system can also include a controller. The controller can also have a JTAG interface for communication with the microprocessor's JTAG interface. The controller can detect defects in the processor socket via the two JTAG interfaces. For example, the controller can direct the processor to send a bit pattern across the multiple pins of the processor socket. By comparing the sent bit pattern with a received bit pattern, the controller can determine whether there are any faults. Such faults may be caused by bent or missing pins in the processor socket. Corrective action may then be taken to rework the socket or discard it. This system can be advantageous since bent or missing pins may be detected more easily and more often.

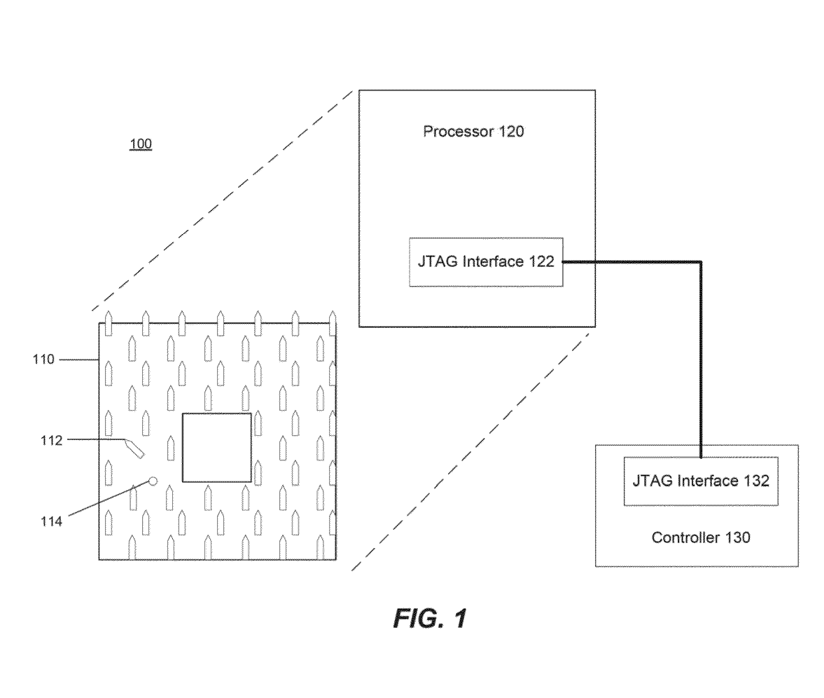

Referring now to the drawings, FIG. 1 illustrates a system 100 for detecting defects in a processor socket. System 100 may be a computer system, such as a desktop computer, workstation computer, server computer, or the like. System 100 may also be simply a printed circuit board or printed circuit assembly.

System 100 may include a socket 110. Socket 110 may be a processor socket, which is sometimes referred to as a CPU socket. A processor socket is a mechanical component that provides mechanical and electrical connections between a microprocessor and a printed circuit board. Processor sockets permit microprocessors to be replaced without soldering. The processor socket may include retention dips. The retention clips may serve to retain an installed processor in the socket.

The processor socket may also include multiple pins. The pins may provide the electrical connection between an installed microprocessor and the printed circuit board. Multiple pins are depicted in FIG. 1, such as pin 112. Many processor sockets include a large number of pins, such as 2000 pins, in one example.

Pin 112 is shown as bent. Pin 112 may have become bent during manufacturing of socket 110 or, more generally, during manufacturing and handling of system 100. Pin 112 may also have become bent during shipping of socket 110 or system 100. Pin 112 may also have become bent when a user installed a microprocessor into the socket, such as if the user replaced a microprocessor that had come with the system. Circle 114 is intended to indicate a missing pin. The missing pin may have broken off during manufacturing, shipping, or handling. The missing pin may also have never been properly installed due to an error in the manufacturing process.

System 100 may also include a processor 120 and a controller 130. Processor 120 and controller 130 may be any of various microprocessors. The microprocessor may include at least one central processing unit (CPU), at least one semiconductor-based microprocessor, at least one digital signal processor (DSP) such as a digital image processing unit, other hardware devices or processing dements suitable to retrieve and execute instructions stored in memory, or combinations thereof. The microprocessor can include single or multiple cores on a chip, multiple cores across multiple chips, or combinations thereof. The processor may fetch, decode, and execute instructions from memory to perform various functions. As an alternative or in addition to retrieving and executing instructions, the controller may include at least one integrated circuit (IC), other control logic, other electronic circuits, or combinations thereof that include a number of electronic components for performing various tasks or functions.

Processor 120 and controller 130 may include memory, such as a machine-readable storage medium. The machine-readable storage medium may be any electronic, magnetic, optical, or other physical storage device that contains or stores executable instructions. Thus, the machine-readable storage medium may comprise, for example, various Random Access Memory (RAM), Read Only Memory (ROM), flash memory, and combinations thereof. For example, the machine-readable medium may include a Non-Volatile Random Access Memory (NVRAM), an Electrically Erasable Programmable Read-Only Memory (EEPROM), a storage drive, a NAND flash memory, and the like. Further, the machine-readable storage medium can be computer-readable and non-transitory.

Processor 120 may include contact pads that may contact the pins in socket 110 to provide an electrical connection between processor 120 and printed circuit assembly on which socket 110 is installed. The dashed lines are intended to indicate that processor 120 can be inserted into socket 110. After insertion, processor 120 may communicate with various devices on the printed circuit assembly via different pads of the processor, and thus through the corresponding pins in socket 110. Bent pin 112 and the missing pin illustrated by circle 114 can thus cause problems. For example, is the processor 120 attempts to communicate to a device on the printed circuit assembly, such as a memory, via either of those pins, the communication may fail.

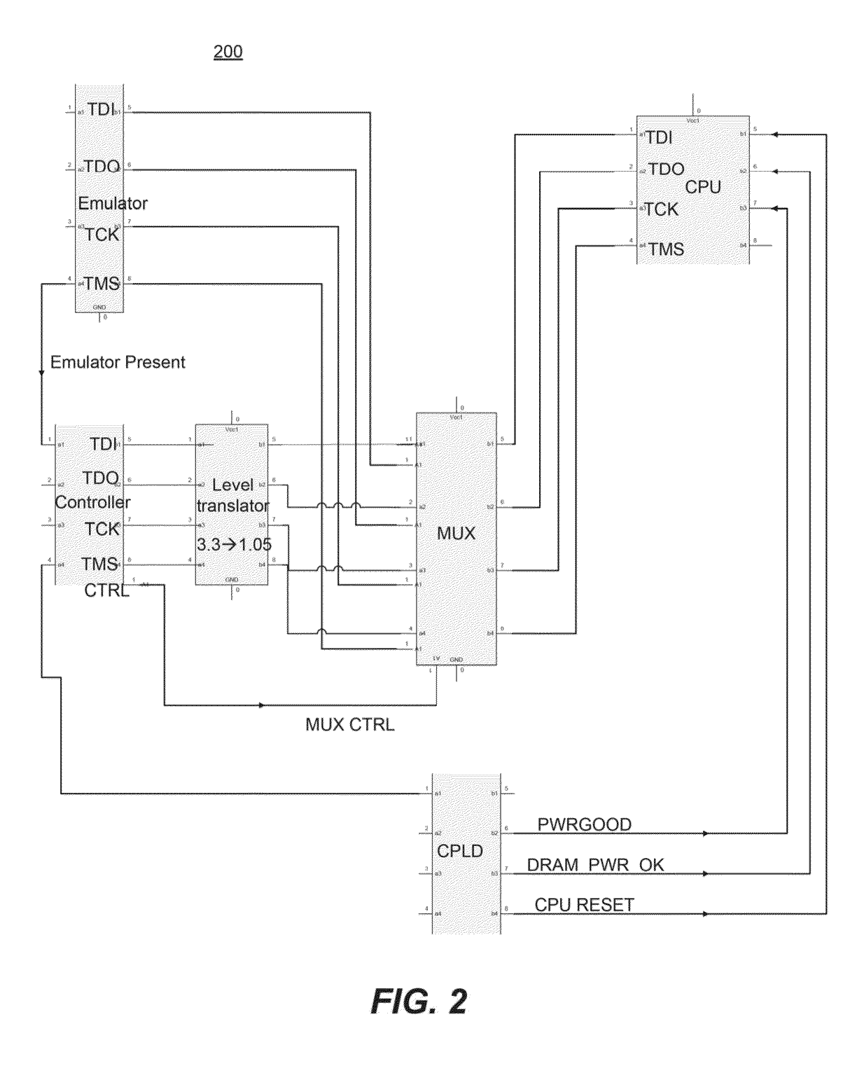

Processor 120 may also include a Joint Test Action Group (JTAG) interface 122. The JTAG interface may be used for testing printed circuit boards using boundary scan. Boundary scan is a technique for testing interconnects on printed circuit boards or sub-blocks inside an integrated circuit, it can also be used for debugging purposes. Boundary scan can be enabled by adding a boundary scan cell to each pad of the processor 120. This is often referred to as latching the cells to the processor pins. During test mode, the cells can override the pads to transmit data and perform tests. Since processor 120 is JTAG compliant, machine readable instructions written in the Boundary Scan Description Language (BSDL) can be used to access the processor and send a bit pattern across the pins. The bit pattern may be optimized to not only detect a fault, but to detect the type of fault, such as shorts between certain pins, specific pins that are disconnected, etc. Additional detail regarding the JTAG interface, such as control lines, will be described below with reference to FIG. 2.

In some examples, controller 130 may be an out-of-band management system. Out-of-band management, sometimes referred to as lights-out management, involves the use of a dedicated management channel for system maintenance. Such management may occur from a remote location, even if the system being managed is not powered on (in this case, the system being managed would include socket 110, processor 120, and the printed circuit assembly that includes socket 110). An example of an out-of-band management system that controller 130 could correspond to is Hewlett-Packard Company's® Integrated Lights-Out (iLO) system.

Controller 130 may include JTAG interface 132. JTAG interface 132 may enable communication with the corresponding JTAG interface 122 of processor 120. Controller 130 may thus perform various tests and debugging via JTAG interface 132 if it is connected to JTAG interface 122. For example, controller 130 may test socket 110 for faults. The presence of faults may be determined to be due to bent or missing pins in socket 110.

In an example, controller 130 may test socket 110 by transmitting a bit pattern across the pins of socket 110 when processor 120 is inserted in socket 110. The bit pattern may be transmitted across the pins via the boundary scan cells. For instance, the bit pattern may be shifted over the pins in a sequential fashion and then may be shifted back to controller 130 via the JTAG interfaces 122, 132. Controller 130 may then compare the sent bit pattern with the received bit pattern to determine if there are any discrepancies between the two. A discrepancy between the bit patterns may indicate that a fault occurred somewhere along the line of socket pins. The controller 130 may be configured to indicate that a fault has been detected. Additionally, the controller 130 may be configured to indicate that the fault was likely caused by a bent or missing pin. The controller 130 may provide these indications in various ways, such as via a graphical user interface on a remote computer or light emitting diodes on a system board. Additionally, the controller 130 can store the fault data in a log.

FIG. 2 illustrates a circuit diagram of a system 200 for detecting defects in a processor socket, according to an example. The CPU can correspond to processor 120 and may be installed in a socket, such as socket 110. Controller may correspond to controller 130. Emulator may be connected to the CPU's JTAG interface for testing and debugging. The emulator may not actually be present in the final system 200, as the emulator might only be used during manufacturing. Accordingly, an emulator interface may be included in a final system, such as system 100, so that the emulator may be connected when needed. In some examples, however, even the emulator interface may be left out and a footprint may be included in the final printed circuit assembly so that the emulator interface may be soldered onto the assembly, in the footprint, if needed.

Level translator may be a voltage level translator. The voltage level translator may translate the voltage level of signals coming from Controller to the appropriate voltage for the JTAG interface on CPU. In this example, the voltage level translator translates Controller's signals from 3.3 volts to 1.05 volts. MUX may be a multiplexer that multiplexes the signals from Controller and Emulator into CPU. Controller may control MUX via the MUX CTRL signal. Controller may be the default, but Controller may switch the MUX to Emulator when the Emulator Present signal is asserted.

The control signals for the JTAG interface are TDI, TDO, TCK, and TMS. Both Emulator and Controller are configured to assert these signals so that they can each perform testing via the JTAG interface. TDI stands for Test Data In and is used to input test data, such as a bit pattern. TDO stands for Test Data Out and is used to output test data. TCK stands for Test Clock and determines the operating frequency. TMS stands for Test Mode Select and can be used to select a test mode.

Accordingly, Controller can transmit a bit pattern via its TDI pin. The voltage level of the signal containing the bit pattern can be translated to an appropriate voltage for CPU by Level translator. Assuming Emulator is not present, MUX will be set to pass signals from Controller to CPU, where the bit pattern can be received via CPU's TDI pin. The bit pattern can be transmitted across the pins in the socket via boundary scan cells and the bit pattern can be output back to Controller via TDO and back through MUX. Controller can then compare the received bit pattern with the sent bit pattern to determine if there are any discrepancies, as described above.

CPLD may be a programmable logic device, such as a Complex Programmable Logic Device or a programmable gate array. When Controller performs testing, it can control CPLD to assert certain signals in order to prevent system shutdown. CPLD can keep CPU in reset mode by asserting CPU RESET. CPLD can also assert PWRGOOD, which is a power good signal for the CPU, and DRAM_PWR_OK, which is a power good signal for the memory. After testing, CPU can be brought to a fully operational state by enabling a power cycle of the system, for example, by de-asserting CPU RESET, PWRGOOD, and DRAM_PWR_OK.

Using this configuration, all pins with a boundary scan cell can be tested. However, some pins may not have a boundary scan cell. For example, CPU RESET, PWRGOOD, and DRAM_PWR_OK may not be connected to a boundary scan cell. Additionally, the processor clock and QPI data links may not be connected to a boundary scan cell.

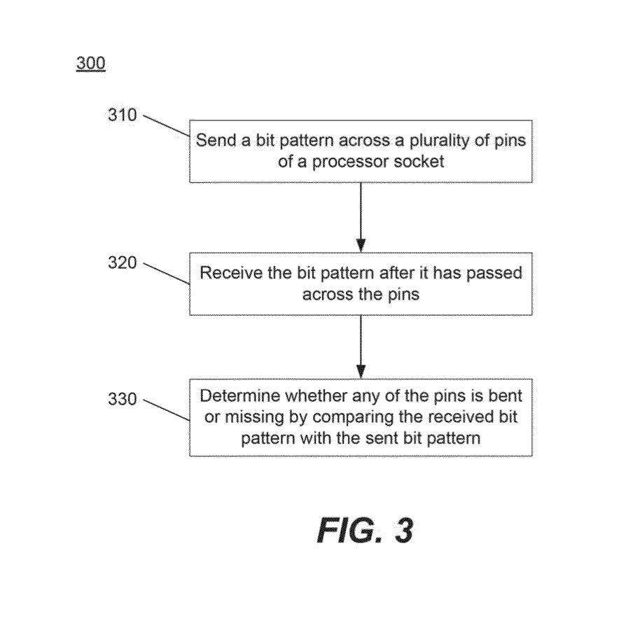

FIG. 3 illustrates a method for detecting defects in a processor socket, according to an example. Method 300 may be implemented by a system, such as system 100 or 200. At 310, a bit pattern may be sent across a plurality of pins of a processor socket. For example, the bit pattern may be sent by a controller, such an out-of-band management system. The bit pattern may be transmitted via a JTAG interface. At 320, the bit pattern can be received after it has passed across the pins. At 330, it can be determined whether any of the pins is bent or missing by comparing the received bit pattern with the sent bit pattern. The appearance of discrepancies between the two bit patterns can indicate that a fault occurred, which can be indicative of a bent or missing pins in the processor socket. In one example, method 300 can be performed before shipping a system that includes the processor socket to a customer. Other features, such as described with respect to systems 100 or 200, may also be implemented as methods.

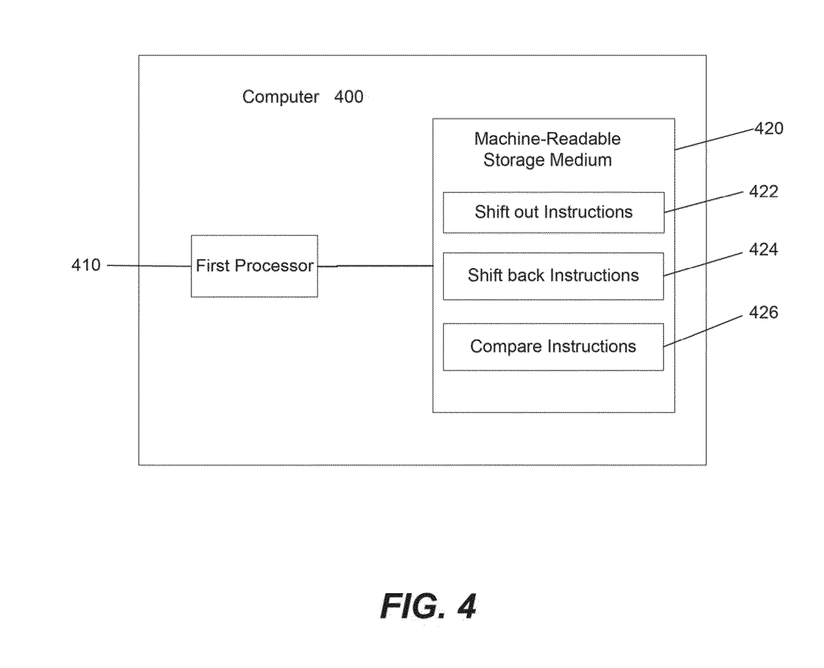

FIG. 4 illustrates a computer-readable medium for detection of defects in a processor socket, according to an example. Computer 400 may be any of a variety of computing devices or systems, such as described with respect to system 100.

First processor 410 may be at least one central processing unit (CPU), at least one semiconductor-based microprocessor, other hardware devices or processing elements suitable to retrieve and execute instructions stored in machine-readable storage medium 420, or combinations thereof. First processor 410 can include single or multiple cores on a chip, multiple cores across multiple chips, multiple cores across multiple devices, or combinations thereof. First processor 410 may fetch, decode, and execute instructions 422, 424, 426 among others, to implement various processing. As an alternative or in addition to retrieving and executing instructions, first processor 410 may include at least one integrated circuit (IC), other control logic, other electronic circuits, or combinations thereof that include a number of electronic components for performing the functionality of instructions 422, 424, 426. Accordingly, first processor 410 may be implemented across multiple processing units and instructions 422, 424, 426 may be implemented by different processing units in different areas of computer 400.

Machine-readable storage medium 420 may be any electronic, magnetic, optical, or other physical storage device that contains or stores executable instructions. Thus, the machine-readable storage medium may comprise, for example, various Random Access Memory (RAM), Read Only Memory (ROM), flash memory, and combinations thereof. For example, the machine-readable medium may include a Non-Volatile Random Access Memory (NVRAM), an Electrically Erasable Programmable Read-Only Memory (EEPROM), a storage drive, a NAND flash memory, and the like. Further, the machine-readable storage medium 420 can be computer-readable and non-transitory. Machine-readable storage medium 420 may be encoded with a series of executable instructions for managing processing elements.

The instructions 422, 424, 426 when executed by first processor 410 (e.g., via one processing element or multiple processing elements of the first processor can cause first processor 410 to perform processes, for example, the processes depicted in FIG. 3 and described with respect to FIGS. 1 and 2. Furthermore, computer 400 may be similar to system 100 or 200 and may have similar functionality and be used in similar ways, as described above.

Shift out instructions 422 can cause first processor 410 to shift a bit pattern out to a plurality of pins in a socket via boundary scan cells. The boundary scan cells may be associated with a JTAG interface of a second processor installed in the socket. Shift back instructions 424 can cause first processor 410 to shift the bit pattern back to the first processor after the bit pattern has passed across the plurality of pins. Compare instructions 426 can cause first processor 410 to compare the shifted out bit pattern with the shifted back bit pattern to determine whether there are any manufacturing defects in the processor socket. The appearance of discrepancies between the two bit patterns can indicate that a fault occurred, which can be indicative of a defect, such as a bent or missing pin in the processor socket.

What is claimed is:

1. A system, comprising:
a socket comprising a plurality of pins;
a processor installed in the socket, the processor comprising a JTAG interface; and
a controller comprising a JTAG interface, the controller configured to test the socket via the JTAG interface to detect any faults in the socket.

2. The system of claim 1, wherein the controller is configured to test the socket by transmitting a bit pattern across the plurality of pins via boundary scan cells, receiving the bit pattern after it has passed across the plurality of pins, and comparing the received bit pattern with the transmitted bit pattern.

3. The system of claim wherein the controller is configured to indicate that one of the plurality of pins is bent if there is a discrepancy between the received bit pattern and the transmitted bit pattern.

4. The system of claim 1, further comprising:
a multiplexer to connect the controller's JTAG interface to the processor's JTAG interface.

5. The system of claim 4 further comprising:
an emulator interface connected to the processor's JTAG interface via the multiplexer,
wherein the controller is configured to control a selection bit for the multiplexer.

6. The system of claim 1, further comprising:
a voltage level translator to translate the voltage output by the controller to the voltage required by the processor.

7. A method of testing a processor socket, comprising:
sending a bit pattern across a plurality of pins of the processor socket;
receiving the bit pattern after it has passed across the plurality of pins; and
determining whether any of the plurality of pins is bent or missing by comparing the received bit pattern with the sent bit pattern.

8. The method of claim 7, further comprising providing an indication that one of the plurality of pins is bent or missing if the received bit pattern differs from the sent bit pattern.

9. The method of claim 7, wherein the bit pattern is sent across the plurality of pins of the processor socket via a JTAG interface.

10. The method of claim 9, further comprising controlling a multiplexer that multiplexes a testing device and a debugging device to the JTAG interface,
wherein the debugging device is connected to the JTAG interface if the debugging device asserts a presence bit.

11. The method of claim 7, wherein the method is performed by an band management system.

12. The method of claim 7, wherein the method is performed before shipping a system comprising the processor socket to a customer.

13. A non-transitory computer-readable storage medium comprising instructions that, when executed by a first processor, cause the first processor to:
shift a bit pattern out to a plurality of pins in a socket via boundary scan cells associated with a JTAG interface of a second processor installed in the socket;
shift the bit pattern back to the first processor after the bit pattern has passed across the plurality of pins; and
compare the shifted out bit pattern with the shifted back bit pattern to determine whether there are any defects in the processor socket.

14. The computer-readable storage medium of claim 13, wherein the first processor is a controller for an out-of-band management system.

15. The computer-readable storage medium of claim 13, further comprising instructions to cause the first processor to maintain the second processor in a RESET mode.
